(19) United States
(12) Patent Application Publication
(10) Pub. No.: US 2015/0124236 A1
(43) Pub. Date: May 7, 2015

(54) LIGHT EXPOSURE SYSTEM AND LIGHT EXPOSURE PROCESS

(71) Applicant: InnoLux Corporation, Jhu-Nan (TW)

(72) Inventors: Cheng-Jui LIN, Jhu-Nan (TW); Yu-Ju CHEN, Jhu-Nan (TW); Chen-Kuan KAO, Jhu-Nan (TW); Chu-Chun CHENG, Jhu-Nan (TW)

(21) Appl. No.: 14/535,012

(22) Filed: Nov. 6, 2014

(30) Foreign Application Priority Data
Nov. 6, 2013 (TW) 102140358

(51) Int. Cl. G03F 7/00

(52) U.S. Cl. CPC G03F 7/0005
USPC 355/77

(57) ABSTRACT

A light exposure system includes a light source device, a shutter device and a control device. The light source device is capable of emitting a light to an assembly liquid crystal cell. The shutter device is located on an optical path of the light. The control device controls the light source device or the shutter device to control the illuminance on the assembly liquid crystal cell. The control device makes the assembly liquid crystal cell have a plurality of first exposure times receiving a first illuminance and a plurality of second exposure times receiving a second illuminance during the light exposure process. The first exposure times and the second exposure times are arranged alternately. The sum of the first exposure times and the second exposure times is substantially equal to the default continuous exposure time.

### CROSS REFERENCE TO RELATED APPLICATIONS

This Non-provisional application claims priority under 35 U.S.C. §119(a) on Patent Application No(s). 102140358 filed in Taiwan, Republic of China on Nov. 6, 2013, the entire contents of which are hereby incorporated by reference.

### BACKGROUND OF THE INVENTION

1. Field of Invention

The invention relates to a light exposure system and a light exposure process and, in particular, to a light exposure system and a light exposure process of an assembly liquid crystal cell.

2. Related Art

With the progress of technologies, flat display devices have been widely applied to various kinds of fields. Especially, liquid crystal display (LCD) devices, having advantages such as compact structure, low power consumption, light weight and less radiation, gradually take the place of cathode ray tube (CRT) display devices and are widely applied to various electronic products, such as mobile phones, portable multimedia devices, notebooks, LCD TVs and LCD screens.

In the multi-domain vertical alignment (MVA) process for enhancing the quality of the TFT LCD, the polymer sustained alignment (PSA) technology is one choice to achieve the mass production and enhance the optical features such as aperture ratio and contrast. In the PSA technology, a photosensitive monomer is mixed with the liquid crystal and applied in the one drop filling (ODF) process, and then a light (e.g. ultraviolet) exposure is executed while a voltage is applied, so that the photosensitive monomers within the liquid crystal molecules are polymerized (to generate a polymer alignment layer). Consequently, the monomers are polymerized according to the electric-field direction caused by the pattern of the patterned transparent conductive layer to affect the arrangement of the LC molecules in pre-tilt angle. Therefore, the alignment of the LC molecules is achieved.

In the commonly used, light exposure system and process of the PSA process, the photosensitive monomers within the LC layer are illuminated by an ultraviolet with fixed wavelength and illuminance for a default continuous light exposure time and thereby polymerized to give the LC molecules a stable alignment and a function of wide viewing angle. However, the LCD panel includes a color filter layer (usually made by photoresist material) for providing a full-color display, and an over coating material or photoresist material also may be used to achieve a high aperture ratio design or avoid the light leakage problem caused by the step difference of the pixel structure, and such organic photoresist material, LC molecules within the panel or polymer thin film (with material such as polyimide, PI) on the glass substrate will be damaged due to the ultraviolet illumination. As a result, the optical performance of the LCD panel will become bad or the reliability test thereof will fail.

### SUMMARY OF THE INVENTION

An objective of the invention is to provide a light exposure system and a light exposure process which can not only give the LC molecules a stable alignment and a function of wide viewing angle but also avoid the damage of the inside components to enhance the optical performance or reliability of the product.

To achieve the above objective, a light exposure system of the invention executes a light exposure process to an assembly liquid crystal cell to polymerize photosensitive monomers within the liquid crystal (LC) into a polymer alignment layer capable of controlling the LC arrangement and comprises a light source device, a shutter device and a control device. The light source device emits a light to the assembly liquid crystal cell. The shutter device is disposed between the light source device and the assembly liquid crystal cell and on an optical path of the light. The control device is electrically connected with the light source device and the shutter device. The control device controls the light source device or the shutter device to control the illuminance of the illumination of the light on the assembly liquid crystal cell during the light exposure process, the control device makes the assembly liquid crystal cell have a plurality of first exposure times receiving a first illuminance and a plurality of second exposure times receiving a second illuminance during the light exposure process, the first illuminance is different from the second illuminance, the first exposure times and the second exposure times are arranged alternately, and the sum of the first exposure times and the second exposure times is substantially equal to a default continuous exposure time, which is required to achieve a default conversion rate, 80%˜100%, of the polymerization of the photosensitive monomers within the LC under a continuous illumination of the light.

In one embodiment, each of the first exposure times is 0.5˜5 times each of the second exposure times.

In one embodiment, the control device controls the light source device or the shutter device to make the second illuminance received by the assembly liquid crystal cell less than the first illuminance during the second exposure times.

In one embodiment, the control device controls the light source device or the shutter device to make the second illuminance received by the assembly liquid crystal cell substantially equal to zero during the second exposure times.

In one embodiment, the shutter device includes a polarizer-type shutter unit, an open-close-type shutter unit, a caterpillar-track-type shutter unit or a louver-type shutter unit.

In one embodiment, the polarizer-type shutter unit includes two polarizers with different polarization axes.

To achieve the above objective, a light exposure process of the invention is applied to an assembly liquid crystal cell to polymerize photosensitive monomers within the liquid crystal (LC) into a polymer alignment layer capable of controlling the LC arrangement, and comprises steps of: a step (A), illuminating the assembly liquid crystal cell with a light of a first illuminance for a first exposure time to polymerize the photosensitive monomers within the LC; a step (B), illuminating the assembly liquid crystal cell with the light of a second illuminance, which is different from the first illuminance, for a second exposure time after the step (A); and repeating the steps (A) and (B), so that the sum of the first exposure times and the second exposure times is substantially equal to a default continuous exposure time, which is required to achieve a default conversion rate, 80%˜100%, of the polymerization of the photosensitive monomers within the LC under a continuous illumination of the light.

In one embodiment, the second illuminance is less than the first illuminance.

In one embodiment, the first exposure time in the step (A) is 0.5˜5 times the second exposure time in the step (B).

In one embodiment, the second illuminance in the step (B) is substantially equal to zero.

In one embodiment, a light source device emits the light to the assembly liquid crystal cell in the step (A), and a control device blocks the illumination of the light source device on the assembly liquid crystal cell in the step (B).

In one embodiment, the control device controls the light source device to be turned off to provide the assembly liquid crystal cell with the second illuminance in the step (B).

In one embodiment, the control device controls a shutter device to block the light of the light source device on the assembly liquid crystal cell to provide the assembly liquid crystal cell with the second illuminance in the step (B).

As mentioned above, in the light exposure system and light exposure process of the invention, a light exposure process is executed to an assembly liquid crystal cell to polymerize the photosensitive monomers within the LC into a polymer alignment layer capable of controlling the LC arrangement. The control device can control the light source device or the shutter device to control the photo dosage that is applied to the assembly liquid crystal cell by the light during the light exposure process. The control device makes the assembly liquid crystal cell have a plurality of first exposure times receiving the first illuminance and a plurality of second exposure times receiving the second illuminance during the light exposure process. The first illuminance is different from the second illuminance, and the first exposure times and the second exposure times are arranged alternately. The sum of the first exposure times and the second exposure times is substantially equal to a default continuous exposure time, which is required to achieve a default conversion rate, 80%˜100%, of the polymerization of the photosensitive monomers within the LC under a continuous illumination. Thereby, the actual total exposure dosage of the light illuminating the assembly liquid crystal cell is less than the default total exposure dosage applied to the assembly liquid crystal cell within the default continuous exposure time. Therefore, the light exposure system and light exposure process can not only cause the stable alignment to the LC molecules of the display panel to achieve the purpose of wide viewing angle but also reduce the damage to the inside components (e.g. organic photoresist material or others) to enhance the optical performance or reliability of the product.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic sectional diagram of a display panel;

FIG. 1B is a schematic sectional diagram of another display panel;

FIGS. 2A and 2B are schematic diagrams showing that a light exposure system executes a light exposure process to an assembly liquid crystal cell according to an embodiment of the invention;

FIGS. 3A, 3B, 4A, 4B, 5A, and 5B are schematic diagrams of different embodiments of the light exposure systems executing the light exposure process to the assembly liquid crystal cell according to the invention;

FIG. 6 is a schematic diagram comparing the light exposure manner of the invention with the light exposure manner of the conventional art;

FIGS. 7A and 7B are schematic diagrams showing the relation between the conversion rate of the photosensitive monomers and the duration of the illumination when the assembly liquid crystal cell is illuminated by the light exposure system of the invention under the condition of different illumination; and

FIG. 8 is a schematic flowchart of a light exposure process according to an embodiment of the invention.

### DETAILED DESCRIPTION OF THE INVENTION

The present invention will be apparent from the following detailed description, which proceeds with reference to the accompanying drawings, wherein the same references relate to the same elements.

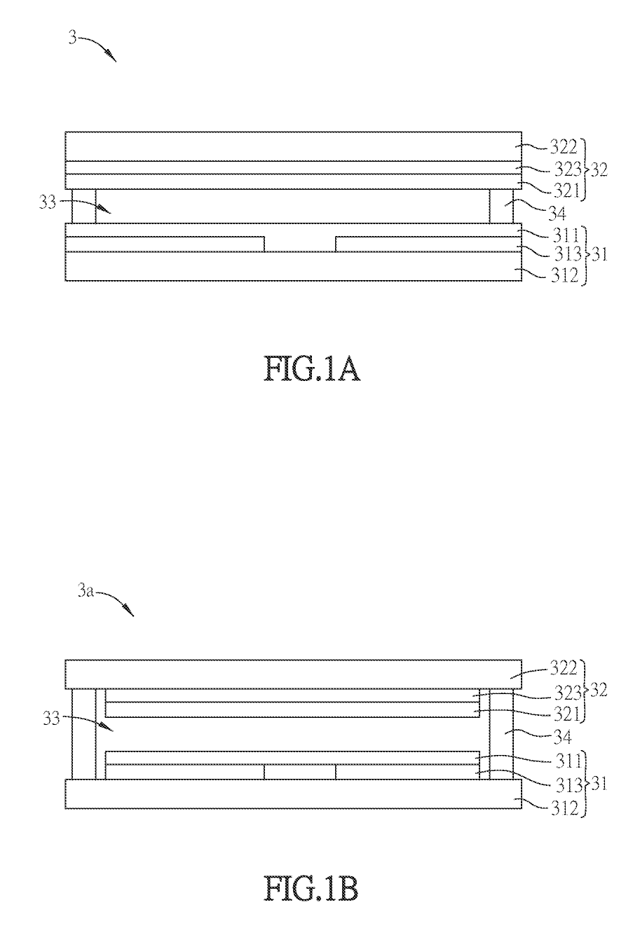

The light exposure system can execute a light exposure process to an assembly liquid crystal cell, so that the photosensitive monomers within the liquid crystal of the assembly liquid crystal cell are polymerized to become a polymer alignment layer that is capable of controlling the arrangement of the liquid crystal. Herein, the so-called assembly liquid crystal cell indicates that the assembly of the upper and lower substrates and the filling of the liquid crystal has been completed but the scribing has not been performed so that the product of a display panel is not generated yet. An assembly liquid crystal cell can include a display panel (including an upper substrate, a lower substrate and a liquid crystal layer) or include a plurality of display panels (including a mother glass defining a plurality of upper substrates, another mother glass defining a plurality of lower substrates and liquid crystal layers, wherein one of the upper substrate, one of the lower substrate and the liquid crystal layer can constitute a display panel). Herein, the number of the display panels included in the assembly liquid crystal cell is not limited. Before illustrating the light exposure system, the structure of a display panel 3, 3a is described by referring to FIGS. 1A and 1B. To be noted, FIGS. 1A and 1B show the structure of a display panel that has been scribed instead of an assembly liquid crystal cell (the assembly liquid crystal cell includes one or a plurality of display panels).

As shown in FIG. 1A, the display panel 3 of this embodiment includes a first substrate 31, a second substrate 32 and a liquid crystal (LC) layer 33 (LC molecules are not shown), and the LC layer 33 is disposed between the first substrate 31 and the second substrates 32. For example, the first substrate 31 is a thin film transistor (TFT) substrate while the second substrate 32 is a color filter (CF) substrate. However, in other embodiments, the black matrix or the color filter layer (with organic photoresist material for example) can be disposed on the TFT substrate, so that the first substrate 31 is called a BOA (BM on array) substrate or a COA (color filter on array) substrate.

The first substrate 31 includes a polymer thin film 311 and a transparent substrate 312, and the second substrate 32 includes a polymer thin film 321 and a transparent substrate 322. The material of the polymer thin films 311 and 321 is, for example but not limited to, polyimide (PI). The polymer thin film 311 is disposed on the side of the transparent substrate 312 facing the second substrate 32, and the polymer thin film 321 is disposed on the side of the transparent substrate 322 facing the first substrate 31. The display panel 3 further includes a photosensitive monomer material (not shown), which can be mixed within the LC layer 33, within the polymer thin films 311 and 321 or/and within the LC layer 33. The first substrate 31 further includes a first transparent conductive layer 313, and the second substrate 32 further includes a second transparent conductive layer 323. The material of the first conductive layer 313 or the second transparent conductive layer 323 is, for example, ITO (indium-tin oxide), IZO (indium-zinc oxide), AZO (aluminum-zinc oxide), GZO, or ZnO (zinc oxide), but the invention is not limited thereto. The first transparent conductive layer 313 is disposed between the transparent substrate 312 and the polymer thin film 311, and the second transparent conductive layer 323 is disposed between the transparent substrate 322 and the polymer thin film 321. The display panel 3 further includes a sealing material (such as a sealant) 34, which is disposed at the edges of the first substrate 31 and the second substrate 32. The sealing material 34, the first substrate 31 and the second substrate 32 form a sealed space, and the LC layer 33 is disposed within the sealed space.

To be noted, in this embodiment, the first transparent conductive layer 313 is a patterned transparent conductive layer and the second transparent conductive layer 323 is a non-patterned transparent conductive layer. In other embodiments, the second transparent conductive layer 323 also can be a patterned transparent conductive layer. The sealing material 34 of this embodiment is disposed between the polymer thin film 311, the first transparent conductive layer 313, the polymer thin film 321 and the second transparent conductive layer 323, and directly contacts the polymer thin films 311 and 321. However, in other embodiments, as shown in FIG. 1B, the polymer thin films 311 and 321 and the first transparent conductive layers 313 and the second transparent conductive layers 323 of the display panel 3a can be disposed within the sealed space formed by the sealing material 34 and the first substrate 31 and the second substrate 32, while the sealing material 34 is disposed between the transparent substrates 312 and 322 and directly contacts the transparent substrates 312 and 322. To be noted, since the assembly liquid crystal cell includes at least a display panel 3 (or 3a), it can be said that the assembly liquid crystal cell includes the above-mentioned components (i.e. the first substrate, second substrate, LC layer, photosensitive monomer material, sealing material, etc.). Besides, the structure of the display panel 3 (or 3a) is just for example but not for limiting the scope of the invention.

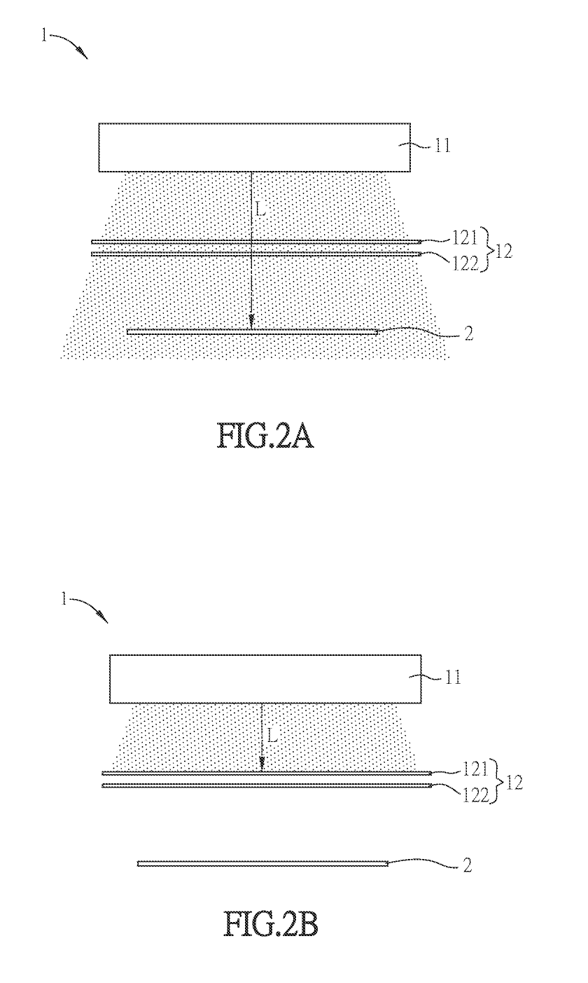

FIGS. 2A and 2B are schematic diagrams showing that a light exposure system 1 executes a light exposure process to an assembly liquid crystal cell 2, which includes at least an above-mentioned display panel 3.

As shown in FIGS. 2A and 2B, the light exposure system 1 of this embodiment can execute the light exposure process to the assembly liquid crystal cell 2, but the invention is not limited thereto. For example, the light exposure system 1 can execute the light exposure process to plural assembly liquid crystal cells 2. Furthermore, the light exposure system 1 includes a cell replacing apparatus (not shown). The cell replacing apparatus includes a robot arm to hold the assembly liquid crystal cell 2 for loading and unloading the assembly liquid crystal cell 2. Herein, the loading operation indicates that the robot arm holds and moves an assembly liquid crystal cell 2 that has not undergone the light exposure process to the stage, and the unloading operation indicates that the robot arm holds and removes the assembly liquid crystal cell 2 that has undergone the light exposure process off the stage. Moreover, after the loading operation of the assembly liquid crystal cell 2 is completed, the light exposure system 1 can execute the preparatory work (for the light exposure), such as cell alignment, electrode contact and electric application, to the assembly liquid crystal cell 2. The purpose of the electric application is to generate an electric field between the first transparent conductive layers 313 and the second transparent conductive layers 323 of the display panel 3, and then the liquid crystal of the liquid crystal layer 33 is arranged according to the pattern (i.e. slit pattern) of the first transparent conductive layer 313 of the first substrate 31. Meanwhile, the light exposure process is executed to polymerize the photosensitive monomers into a polymer alignment layer so as to achieve the purpose of the LC alignment, and therefore the aperture ratio, view angle and optical performance such as contrast of the LCD panel can be improved.

Since the assembly liquid crystal cell 2 includes at least a display panel 3 containing photosensitive monomer material mixed in the liquid crystal layer 33 (or in the polymer thin films 311, 312 or in the liquid crystal 33 and the polymer thin films 311, 321 simultaneously), the photosensitive monomer material is illuminated by a light with a default wavelength (e.g. ultraviolet) and a fixed intensity for a default continuous exposure time in the conventional PSA exposure process so as to achieve a sufficient conversion rate (i.e. a default conversion rate) of the polymerization of the photosensitive monomers for the purpose of the LC alignment. In consideration of the influence of the anchoring force and residual monomer rate upon the LC, the default continuous exposure time should be set to make the conversion rate of the photosensitive monomers reach 80% or more. Moreover, different photosensitive monomers may require different default continuous exposure times, and this is the definition of the default continuous exposure time of the light exposure process. Therefore, the default continuous exposure time of the assembly liquid crystal cell 2 will change due to different added photosensitive monomers. For example, the photosensitive monomer material having aromatic ring is used and illuminated by the ultraviolet with a fixed wavelength, and the required default continuous exposure time is about 120 minutes. In order to clearly illustrate the techniques of the invention, the concept of the photo dosage is used, and the definition of the photo dosage is the integral of the illuminance (luminous flux incident on a surface per unit area) over time, which is generally known by those skilled in the art. Hence, for the default continuous exposure time in the PSA process, the light L illuminating the assembly liquid crystal cell 2 also has a default total exposure dosage.

The light exposure system 1 includes a light source device 11, a shutter device 12 and a control device (not shown).

The light source device 11 includes at least a light emitting element (not shown), which can emit a light L to the assembly liquid crystal cell 2 so that the photosensitive monomers mixed in the liquid crystal layer or polymer thin film of the assembly liquid crystal cell 2 can be photo-cured. Herein, the light L emitted by the light emitting element can be a parallel light or a divergent light and can be ultraviolet, infrared light, x-ray or visible light for example. In this embodiment, the light L emitted by the light source device 11 is divergent ultraviolet with a fixed intensity for example.

The shutter device 12 is disposed between the light source device 11 and the assembly liquid crystal cell 2 and located on the optical path of the light L. In other words, the light L emitted by the light source device 11 can reach the assembly liquid crystal cell 2 by passing through the shutter device 12. The shutter device 12 can be a light blocking control device, for example, a polarizer-type shutter unit, an open-close-type shutter unit, a caterpillar-track-type shutter unit or a louver-type shutter unit. Herein, the polarizer-type shutter unit is taken as an example. The polarizer-type shutter unit at least includes two polarizers 121, 122 with different polarization axis. The combination of the polarizers 121, 122 can control the polarization direction of the light L (e.g. just allowing the light L of a certain direction to pass through). The polarization axes of the polarizers 121, 122 can have an angle difference of 90 degrees (i.e. perpendicular to each other), or the angle difference between the polarization axes of the polarizers 121, 122 can be provided differently to control the photo dosage passing therethrough. Herein, the polarization axes of the polarizers 121, 122 are perpendicular to each other)(90°) for example. As shown in FIG. 2A, when the polarization axes of the polarizers 121, 122 are parallel to each other, the light L of a certain direction can be allowed to pass through. As shown in FIG. 2B, when the polarization axes of the polarizers 121, 122 are perpendicular to each other, the light L can be shielded. Thereby, the illuminance applied to the assembly liquid crystal cell 2 can be controlled, and the light L illuminating the assembly liquid crystal cell 2 can become a non-continuous light with less luminous flux, which can be called a pulse-type illumination (i.e. the light L passing through at a time and rarely passing through at another time). Moreover, the frequency of the pulse-type illumination on the assembly liquid crystal cell 2 is not limited.

The control device is electrically connected with the light source device 11 and the shutter device 12. The control device can control the light source device 11 or the shutter device 12, or control both of the light source device 11 and the shutter device 12, to further control the photo dosage (light illuminating energy) of the light L illuminating the assembly liquid crystal cell 2. The control device can make the assembly liquid crystal cell 2 have a plurality of first exposure times with a first illuminance and a plurality of second exposure times with a second illuminance during the light exposure process. Herein, the illuminance is equal to the luminous flux incident on a unit area. The first exposure times and the second exposure times are arranged alternately, which means that the illumination of the first illuminance lasts for the first exposure time, then the illumination of the second illuminance lasts for the second exposure time, and repeats. Moreover, the sum of the first exposure times and the second exposure times given to the assembly liquid crystal cell 2 is substantially equal to the default continuous exposure time of the light exposure process for the assembly liquid crystal cell 2. To be noted, the all first exposure times are unnecessarily equal to each other and the all second exposure times are unnecessarily equal to each other in this invention. However in consideration of the stability of the process, the ratio of the first exposure time to the second exposure time is set as a fixed value for a favorable embodiment.

In this embodiment, as shown in FIG. 2A, the control device controls the polarization axes of the polarizers 121, 122 of the shutter device 12 in order to control the duration and photo energy of the illumination of the light L on the assembly liquid crystal cell 2, so that the assembly liquid crystal cell 2 receives the multiple first exposure times of the first illuminance and the multiple second exposure times of the second illuminance during the light exposure process (the first exposure times and the second exposure times are arranged alternately). In other words, the illumination of the light L of this embodiment is a pulse-type and non-continuous manner, different from the continuous illumination executed during the conventional PSA process.

For example, the illumination of the light L with a fixed intensity on an assembly liquid crystal cell 2 during the conditional PSA process needs to be executed continuously for 100 minutes so that the photosensitive monomers can be photo-cured and the stable alignment of the LC molecules can be achieved, and the said 100 minutes is the default continuous exposure time. However, under the control of the polarizers 121, 122 of the polarizer-type shutter unit of this embodiment, the illumination of the light L on the assembly liquid crystal cell 2 lasts for 10 minutes (with the first illuminance), then the illumination of the light L on the assembly liquid crystal cell 2 is changed for 10 minutes (i.e. the second illuminance is substantially zero), and so on (each of the first exposure time is 10 minutes and each of the second exposure time is 10 minutes). Accordingly, the sum of the first exposure times of the assembly liquid crystal cell 2 receiving the first illuminance (i.e. the actual exposure time) is 50 minutes, and the sum of the second exposure times of the assembly liquid crystal cell 2 receiving the second illuminance (i.e. the actual non-exposure time) is also 50 minutes. Hence, the sum of the first exposure times and the second exposure times is also equal to the default exposure time (100 minutes).

In this embodiment, the control device controls the shutter device 12 to block the light L, so that the assembly liquid crystal cell 2 won't be illuminated by the light of the light source device 11 during the second exposure times. However, in other embodiments, the assembly liquid crystal cell 2 also can't be illuminated by the light of the light source device 11 when the control device controls the light source device 11 to be turned off. In other embodiments, the second illuminance is unnecessarily equal to zero, and for example, the second illuminance emitted by the light source device 11 can be controlled to be half the first illuminance or less than the first illuminance during the second exposure time by the control device. Moreover, the first exposure time is 1 time the second exposure time (10 minutes each) in this embodiment, but this is just for the illustration. In other embodiments, the first exposure time can be 0.5˜5 times the second exposure time, or the ratio therebetween can be varied.

Since the photo energy can be obtained by the integral of the illuminance over time, the actual total exposure dosage received by the assembly liquid crystal cell 2 with the light exposure process will be less than the exposure dosage with the conditional PSA process. Thereby, the actual total exposure dosage of the light can not only cause the stable alignment to the LC molecules of the assembly liquid crystal cell 2 to achieve the purpose of wide viewing angle but also reduce the damage to the inside components (e.g. organic photoresist material or others) to enhance the optical performance or reliability of the product. Although the actual exposure time of the light exposure process is less than the default continuous exposure time and the actual total exposure dosage is less than the default total exposure dosage, the photosensitive monomers within the LC layer still can react completely under the situation of receiving less photo energy, which is in relation to the diffusion effect induced by the concentration difference of the monomers caused by the regional uneven polymerization of the photosensitive monomers within the LC layer.

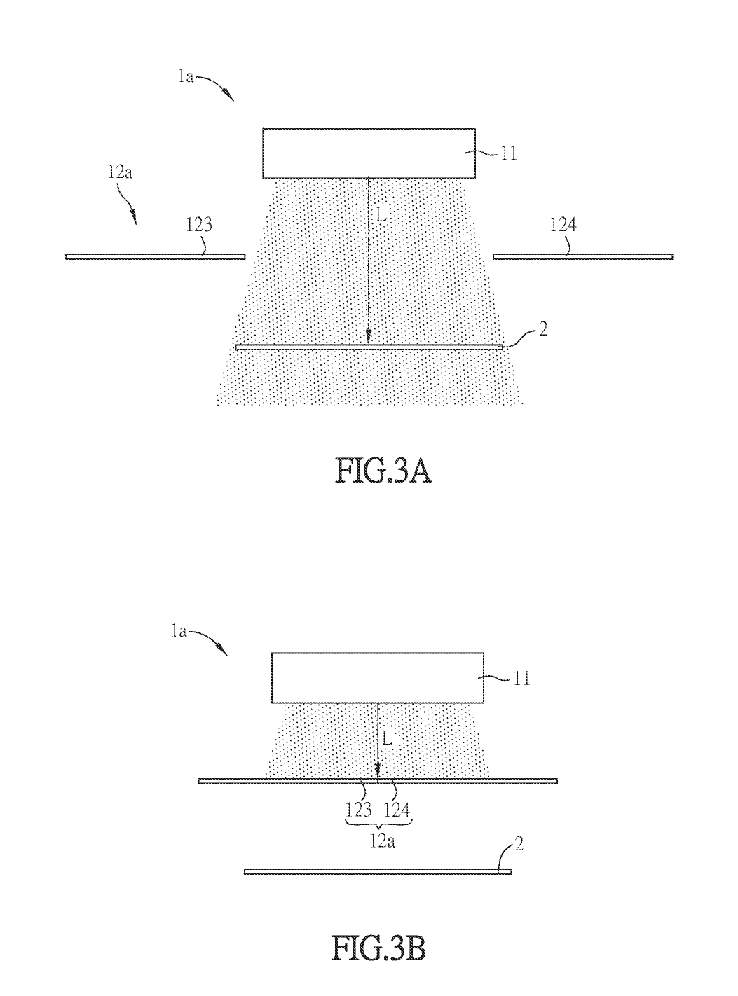

FIGS. 3A to 5B are schematic diagrams of different embodiments of the light exposure systems 1a, 1b, 1c executing the light exposure process to the assembly liquid crystal cell 2.

As shown in FIGS. 3A and 3B, the shutter device 12a of the light exposure system 1a is an open-close-type shutter unit, mainly different from the light exposure system 1 in FIGS. 2A and 2B. The open-close-type shutter unit includes at least two shutter elements 123, 124 which can be situated at an open state and a close state. When the shutter elements 123, 124 are controlled to move towards the opposite sides into the open state by the control device, the light L passes through the shutter device 12a to illuminate the assembly liquid crystal cell 2. When the shutter elements 123, 124 are controlled to move towards the center into the close state, the light L is shielded. Thereby, the actual exposure time of the light L illuminating the assembly liquid crystal cell 2 will be less than the default continuous exposure time, and the actual total exposure dosage will be also less than the default total exposure dosage (the sum of the all first exposure times and the all second exposure times is still equal to the default continuous exposure time).

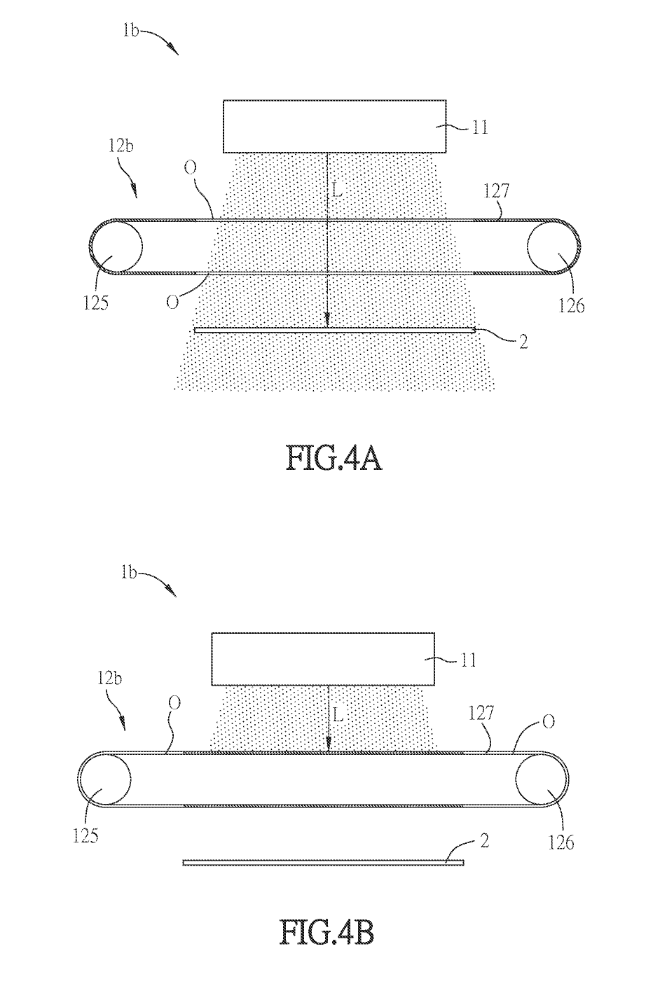

As shown in FIGS. 4A and 4B, mainly different from the light exposure system 1 in FIGS. 2A and 2B, the shutter device 12b of the light exposure system 1b is a caterpillar-track-type shutter unit. The caterpillar-track-type shutter unit includes two rollers 125, 126 and a conveyer belt 127 having at least an opening (each of the upper side and the lower side of the conveyer belt 127 has an opening O for example). The rollers 125, 126 are disposed on the two sides of the inside of the conveyer belt 127, respectively, and the conveyer belt 127 can be rolled by the control device controlling the rotation of the rollers 125, 126. When the conveyer belt 127 is rolled, the light L sometimes will pass through the openings O of the conveyer belt 127 to illuminate the assembly liquid crystal cell 2, sometimes will be partially blocked by the conveyer belt 127 to partially illuminate the assembly liquid crystal cell 2, and sometimes will be completely blocked. Thereby, the actual exposure time of the illumination of the light L on the assembly liquid crystal cell 2 will be less than the default continuous exposure time, and the actual total exposure dosage will be also less than the default total exposure dosage (the sum of the all first exposure times and the all second exposure times is still equal to the default continuous exposure time).

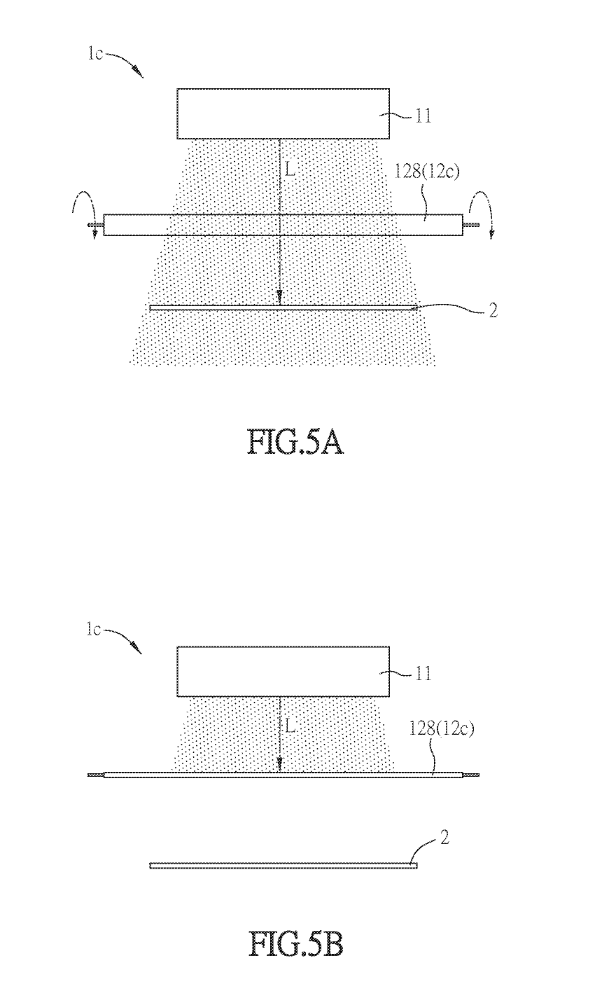

As shown in FIGS. 5A and 5B, mainly different from the light exposure system 1 in FIGS. 2A and 2B, the shutter device 12c of the light exposure system 1c is a louver-type shutter unit. The louver-type shutter unit includes at least a louver element 128. The control device can control the open state and close state of the louver element 128 to control the duration and energy of the illumination of the light L on the assembly liquid crystal cell 2 through the louver element 128. Thereby, the actual exposure time of the illumination of the light L on the assembly liquid crystal cell 2 will be less than the default continuous exposure time, and the actual total exposure dosage will be also less than the default total exposure dosage (the sum of the all first exposure times and the all second exposure times is still equal to the default continuous exposure time).

Since other technical features of the light exposure systems 1a, 1b, 1c can be comprehended by referring to the light exposure system 1, they are not described here for conciseness.

To be noted, in the above embodiments, the wavelength and intensity of the light L emitted by the light source device 11 are both fixed and the control device controls the shutter device 12, 12a, 12b, 12c, in order to control the exposure duration and energy of the illumination of the light L on the assembly liquid crystal cell 2. However, in other embodiments, the control device also can change the light intensity of the light L illuminating the assembly liquid crystal cell 2, and thereby the first exposure time of the first illuminance and the second exposure time of the second illuminance can be controlled so that the actual total exposure dosage on the assembly liquid crystal cell 2 can be less than the default total exposure dosage.

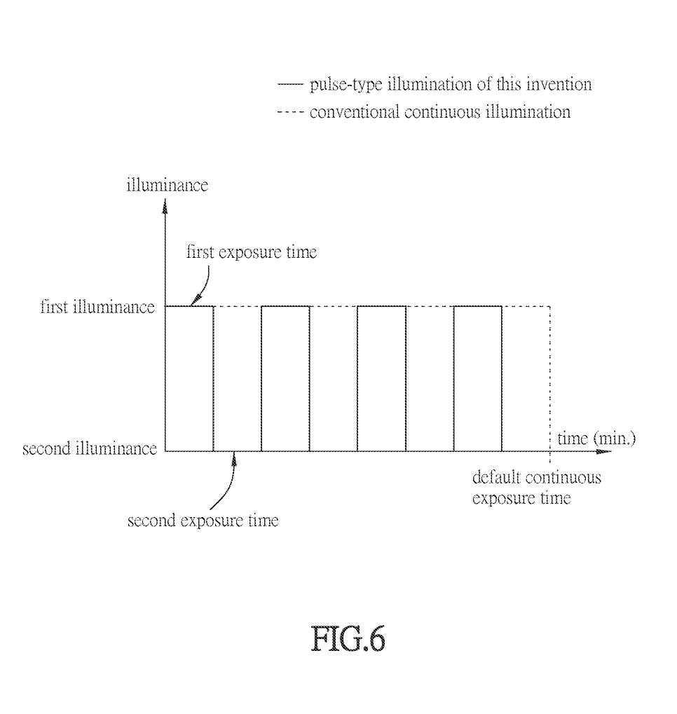

The illustration of the total exposure dosage is shown as FIG. 6. In optics, the photo dosage is generally defined as the integral of the illuminance over time, i.e. the area under the curve in FIG. 6. In the embodiment of FIG. 6, the first exposure time is equal to the second exposure time, and the second illuminance received by the assembly liquid crystal cell during the second exposure time is substantially equal to zero. From the calculation result of FIG. 6, it can be known that the actual total exposure dosage received by the assembly liquid crystal cell of this embodiment is less than the default total exposure dosage in the conventional continuous light exposure process by the value of the area of the second exposure time. Therefore, it is obvious that the illuminance of the pulse-type is used in this invention to cause the photosensitive monomers of the LC to achieve the default conversion rate due to the diffusion, in cooperation with the control of the time.

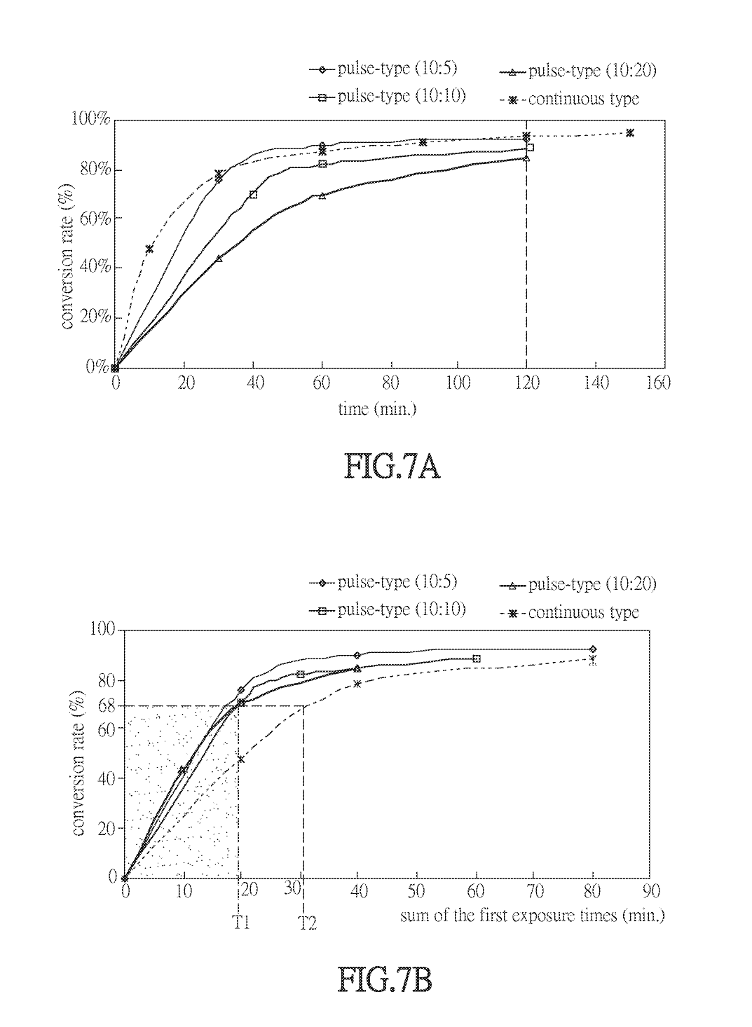

FIGS. 7A and 7B are schematic diagrams showing the relation between the conversion rate of the photosensitive monomers and the exposure duration when the assembly liquid crystal cell 2 is illuminated by the above-mentioned light exposure system 1 under the condition of different illuminance and exposure time. The definition of the conversion rate is the proportion of the photosensitive monomers turned into the polymer alignment layer. The higher conversion rate represents the more complete photo-curing of the monomers and less the residue monomers. The continuous type in FIGS. 7A and 7B represents the conventional light exposure process where the continuous illumination is applied to the assembly liquid crystal cell 2 for the default continuous exposure time (e.g. 120 minutes) to achieve the default conversion rate. The pulse-type (10:10) in FIGS. 7A and 7B represents the illumination is executed for 10 minutes (the first exposure time) and then stopped for 10 minutes (the second exposure time with the illuminance of zero substantially), which indicates the PSA exposure process is still executed for 120 minutes but the actual exposure time is just 60 minutes. The rest can be deduced by analogy.

As shown in FIG. 7A, it can be found that the conversion rate can be obtained as near the result of the continuous illumination by the pulse-type illumination where the light exposure system 1 illuminates the assembly liquid crystal cell 2 for the default continuous exposure time (e.g. 120 minutes), because of the above-mentioned diffusion effect. In other words, even though the illumination is stopped, a polymerization of the photosensitive monomers will react continuously from the direct illumination region (i.e. non-circuit coverage) to the indirect illumination region (i.e. circuit coverage) due to the diffusion effect, and then will be polymerized during the next illumination. Hence, the effectiveness of the light exposure system 1 is validated.

FIG. 7B is derived from the calculation of FIG. 7A, showing the relation between the conversion rate and the sum of duration of a certain illuminance (the same as the first illuminance while the second illuminance is zero). From FIG. 7B, it can be known that the required illumination time T1 (i.e. the sum of the required first exposure times) of the first illuminance is less than the required illumination time T2 of the conventional continuous light exposure process for achieving the same conversion rate (e.g. 68%). Besides, after the integral calculation, it can be known that the total exposure dosage of the pulse-type illumination of this invention is less than that of the conventional continuous illumination for achieving the same conversion rate. Therefore, for achieving the same conversion rate, the total exposure dosage that the light exposure system 1 gives to the assembly liquid crystal cell 2 is less so that the damage to the inside components (e.g. the organic photoresist material or others) of the assembly liquid crystal cell 2 can be reduced.

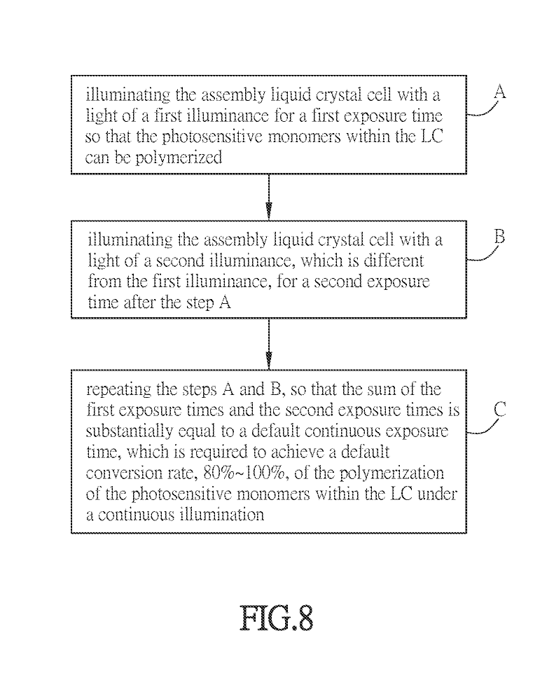

The light exposure process will be illustrated by referring to FIGS. 2A, 2B, 8. FIG. 8 is a schematic flowchart of a light exposure process according to an embodiment of the invention.

The light exposure process is applied to the assembly liquid crystal cell 2 by the light exposure system 1 so that the photosensitive monomers within the LC can be polymerized into the polymer alignment layer that is capable of controlling the arrangement of the LC. The photosensitive monomers of the assembly liquid crystal cell 2 has a default continuous exposure time under a continuous illumination of the light with a default wavelength. The light exposure system 1 includes a light source device 11, a shutter device 12 and a control device. The light source device 11 is capable of emitting a light L. The shutter device 12 is disposed between the light source device 11 and the assembly liquid crystal cell 2 and on the optical path of the light L. The control device is electrically connected with the light source device 11 and the shutter device 12. The assembly liquid crystal cell 2 needs to be moved and loaded by a cell replacing apparatus for example, and is thus disposed under the light exposure system 1 and on the optical path of the light L so that the light L can be emitted to the assembly liquid crystal cell 2. After the loading operation is finished, the preparatory work, such as cell alignment, electrode contact and electric application, for the assembly liquid crystal cell 2 can be performed, as shown in FIG. 7 including the three steps A, B, C.

First, the step A is illuminating the assembly liquid crystal cell 2 with a light of a first illuminance for a first exposure time so that the photosensitive monomers within the LC can be polymerized. As shown in FIG. 2A, the control device controls the polarizers 121, 122 of the shutter device 12 to allow the light L to pass through the polarizers 121, 122 to illuminate the assembly liquid crystal cell 2 with a default wavelength, so that the assembly liquid crystal cell 2 has a first exposure time. Thereby, the photosensitive monomers mixed in the LC layer 33 and/or in the polymer thin films 311, 312 can be polymerized.

Then, the step B is illuminating the assembly liquid crystal cell 2 with a light of a second illuminance, which is different from the first illuminance, for a second exposure time after the step A. The first exposure time in the step A is 0.5˜5 times the second exposure time in the step B. In this embodiment, as shown in FIG. 2B, the light L is blocked by the polarizers 121, 122 not to illuminate the assembly liquid crystal cell 2, so that the second illuminance within the second exposure time is substantially zero.

Then, the step C is repeating the steps A and B, so that the sum of the first exposure times and the second exposure times is substantially equal to a default continuous exposure time, which is required to achieve a default conversion rate, 80%˜100%, of the polymerization of the photosensitive monomers within the LC under a continuous illumination.

Since other technical features of the light exposure process and light exposure system 1 can be comprehended by referring to the above illustration, they are not described here for conciseness.

Summarily, in the light exposure system and light exposure process of the invention, a light exposure process is executed to an assembly liquid crystal cell to polymerize the photosensitive monomers within the LC into a polymer alignment layer capable of controlling the LC arrangement. The control device can control the light source device or the shutter device to control the photo dosage applied to the assembly liquid crystal cell by the light during the light exposure process. The control device makes the assembly liquid crystal cell have a plurality of first exposure times receiving the first illuminance and a plurality of second exposure times receiving the second illuminance during the light exposure process. The first illuminance is different from the second illuminance, and the first exposure times and the second exposure times are arranged alternately. The sum of the first exposure times and the second exposure times is substantially equal to a default continuous exposure time, which is required to achieve a default conversion rate, 80%˜100%, of the polymerization of the photosensitive monomers within the LC under a continuous illumination. Thereby, the actual total exposure dosage of the light illuminating the assembly liquid crystal cell is less than the default total exposure dosage applied to the assembly liquid crystal cell within the default continuous exposure time. Therefore, the light exposure system and light exposure process can not only cause the stable alignment to the LC molecules of the display panel to achieve the purpose of wide viewing angle but also reduce the damage to the inside components (e.g. organic photoresist material or others) to enhance the optical performance or reliability of the product.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light exposure system executing a light exposure process to an assembly liquid crystal cell to polymerize photosensitive monomers within the liquid crystal (LC) into a polymer alignment layer capable of controlling the LC arrangement, comprising:
a light source device emitting a light to the assembly liquid crystal cell;
a shutter device disposed between the light source device and the assembly liquid crystal cell and on an optical path of the light; and
a control device electrically connected with the light source device and the shutter device, wherein the control device controls the light source device or the shutter device to control the illuminance of the illumination of the light on the assembly liquid crystal cell during the light exposure process, the control device makes the assembly liquid crystal cell have a plurality of first exposure times receiving a first illuminance and a plurality of second exposure times receiving a second illuminance during the light exposure process, the first illuminance is different from the second illuminance, the first exposure times and the second exposure times are arranged alternately, and the sum of the first exposure times and the second exposure times is substantially equal to a default continuous exposure time, which is required to achieve a default conversion rate, 80%˜100%, of the polymerization of the photosensitive monomers within the LC under a continuous illumination of the light.

2. The light exposure system as recited in claim 1, wherein each of the first exposure times is 0.5˜5 times each of the second exposure times.

3. The light exposure system as recited in claim 1, wherein the control device controls the light source device or the shutter device to make the second illuminance received by the assembly liquid crystal cell less than the first illuminance during the second exposure times.

4. The light exposure system as recited in claim 1, wherein the control device controls the light source device or the shutter device to make the second illuminance received by the assembly liquid crystal cell substantially equal to zero during the second exposure times.

5. The light exposure system as recited in claim 1, wherein the shutter device is a polarizer-type shutter unit, or an open-close-type shutter unit, or a caterpillar-track-type shutter unit or a louver-type shutter unit.

6. The light exposure system as recited in claim 5, wherein the polarizer-type shutter unit includes two polarizers with different polarization axes.

7. A light exposure process applied to an assembly liquid crystal cell to polymerize photosensitive monomers within the liquid crystal (LC) into a polymer alignment layer capable of controlling the LC arrangement, comprising steps of:
a step (A), illuminating the assembly liquid crystal cell with a light of a first illuminance for a first exposure time to polymerize the photosensitive monomers within the LC;
a step (B), illuminating the assembly liquid crystal cell with the light of a second illuminance, which is different from the first illuminance, for a second exposure time after the step (A); and
repeating the steps (A) and (B), so that the sum of the first exposure times and the second exposure times is substantially equal to a default continuous exposure time, which is required to achieve a default conversion rate, 80%˜100%, of the polymerization of the photosensitive monomers within the LC under a continuous illumination of the light.

8. The light exposure process as recited in claim 7, wherein the second illuminance is less than the first illuminance.

9. The light exposure process as recited in claim 7, wherein the first exposure time in the step (A) is 0.5˜5 times the second exposure time in the step (B).

10. The light exposure process as recited in claim 7, wherein the second illuminance in the step (B) is substantially equal to zero.

11. The light exposure process as recited in claim 7, wherein a light source device emits the light to the assembly liquid crystal cell, and a shutter device blocks the illumination of the light from the light source device on the assembly liquid crystal cell in the step (B).

12. The light exposure process as recited in claim 10, wherein a control device controls the light source device to be turned off to provide the assembly liquid crystal cell with the second illuminance in the step (B).

13. The light exposure process as recited in claim 11, wherein a control device controls the shutter device to block the light of the light source device on the assembly liquid crystal cell to provide the assembly liquid crystal cell with the second illuminance in the step (B).
